(19) United States
(12) Patent Application Publication
(10) Pub. No.: US 2026/0182085 A1
(43) Pub. Date: Jun. 25, 2026

(54) ELECTRONIC CHIP WITH PROTECTIVE WINDOW OVER OPTICAL COMPONENT

(71) Applicant: STMicroelectronics International N.V., Geneva (CH)

(72) Inventors: Romain COFFY, Voiron (FR); Younes BOUTALEB, Grenoble (FR)

(73) Assignee: STMicroelectronics International N.V., Geneva (CH)

(21) Appl. No.: 19/424,356

(22) Filed: Dec. 18, 2025

(30) Foreign Application Priority Data
Dec. 23, 2024 (FR) FR2415135

(51) Int. Cl. H10F 77/50; G02B 27/00; H10F 39/00

(52) U.S. Cl. CPC H10F 77/50; G02B 27/0006; H10F 39/811

(57) ABSTRACT

An integrated circuit chip includes a chip substrate with an optical component at a first surface of the chip substrate. The first surface further includes at least one electrical connection pad. An electrical connection structure is mounted to the electrical connection pad. A protective window is arranged over the optical component. The protective window is bonded to the first surface of the chip substrate by an adhesive layer. The adhesive layer extends at the periphery of the optical component and laterally encases the electrical connection structure. The protective window includes at least one opening aligned with and configured to support making electrical connection to the electrical connection structure.

### PRIORITY CLAIM

This application claims the priority benefit of French Application for Patent No. FR2415135, filed on December 23, 2024, the content of which is hereby incorporated by reference in its entirety to the maximum extent allowable by law.

### TECHNICAL FIELD

The present disclosure generally concerns electronic and/or optical systems and devices and, in particular, electronic/optical chips and their manufacturing methods. More specifically, the present disclosure concerns an electronic chip comprising optical components and a protective window for these optical components.

### BACKGROUND

Optical components, such as optical sensors, are most often used within an electronic and optical chip. These components can be fragile, and their operation may be impaired by dust or debris.

It would be desirable to be able to improve, at least partly, the forming of electronic chips comprising optical components, and the implementation of their manufacturing methods.

There exists a need for chips comprising optical components in which the optical components are protected from dust and debris.

There exists a need for chips comprising optical components in which the optical components are protected from dust and debris by a protective window.

There exists a need for methods of manufacturing such chips, in which the protective window is installed before the forming of dust or of debris.

There is a need in the art to overcome all or part of the disadvantages of known chips comprising optical components.

### SUMMARY

An embodiment provides a chip comprising: a substrate; at least one optical component formed on a first surface of said substrate; at least one electrical connection pad formed on said first surface of said substrate, and topped by an electrical connection structure; and a protective window arranged over said at least one component and secured to said first surface of said substrate by an adhesive layer extending at least partly at the periphery of said at least one component, said window comprising at least one opening configured to make said electrical connection structure accessible.

Another embodiment provides a chip manufacturing method comprising the following successive steps: providing a structure comprising at least one optical component arranged on a first surface of a substrate and at least one electrical connection pad arranged on said first surface of said substrate, said at least one electrical connection pad being topped by an electrical connection structure; depositing an adhesive layer extending at least partly at the periphery of said at least one component; and arranging a protective window over said at least one component and securing it via said adhesive layer, said window comprising at least one opening configured to make said electrical connection structure accessible.

According to an embodiment, said adhesive layer has a thickness smaller than the height of said electrical connection structure.

According to an embodiment, said electrical connection structure comprises one or more solder balls or a conductive pillar.

According to an embodiment, an upper surface of said adhesive layer does not exceed more than 70% of the thickness of said protective window.

According to an embodiment, the adhesive of said adhesive layer is an electrically-insulating adhesive.

According to an embodiment, said at least one opening has a generally rectangular shape.

According to an embodiment, said at least one opening has a generally rectangular and open shape.

According to an embodiment, said at least one opening is configured to make the electrical connection structure topping another connection pad accessible.

According to an embodiment, said at least one opening is obtained by implementing a reactive ion etching operation or a laser etching operation.

According to an embodiment, said window is an untreated glass window or a glass window comprising one or more optical filters.

According to an embodiment, the at least one optical component is an optical sensor.

Still another embodiment provides an electronic device comprising a previously-described chip and a package.

According to an embodiment, said electrical connection structure is coupled to a connection terminal of said package via a wire bonding wire.

Still another embodiment provides a method of manufacturing a previously-described device, comprising the previously-described method.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an embodiment of an electronic chip;

FIG. 2 shows views (A) and (B), each illustrating an embodiment of a protective window for an electronic chip;

FIG. 3 shows views (A) to (E), each illustrating an implementation mode of a method of manufacturing the chip of FIG. 1; and

FIG. 4 shows views (A) to (C) illustrating different options for connecting the chip of FIG. 1.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10%, preferably of plus or minus 5%.

The embodiments described hereafter concern the forming of a chip comprising one or more optical components, for example a plurality of optical lenses, and, at the periphery of these components, electrical connection pads. These embodiments more particularly concern the protection of these optical components from dust and debris. In these embodiments, an optically transparent window, for example, made of glass, is used to protect these optical components. This glass window is secured above the optical components via an adhesive layer and comprises openings to allow electrical connection of the electrical connection pads.

Further, the embodiments described hereafter are particularly configured to any optical and electronic device which uses optical components, for example to capture images (camera).

Further, the above-described embodiments are particularly configured to be used in any type of industrial market where a chip comprising an optical component is used. More particularly, such a chip may be intended for: the automotive industry, for example in the field of automotive electrification or in the field of advanced driver assistance systems (ADAS); the industrial sector, for example in the field of green energy, in the field of infrastructure electrification, of the Internet of Things (IoT) and of smart homes, where electricity and energy consumption and data exchange are key elements; the personal electronics industry, for example in the field of mobile telephony and of the Internet of Things (IoT), as well as in the field of high-speed interfaces; and the communications equipment, computer and peripherals industry, for example in the field of infrastructure and data centers, and in the field of low earth orbit (LEO) satellites.

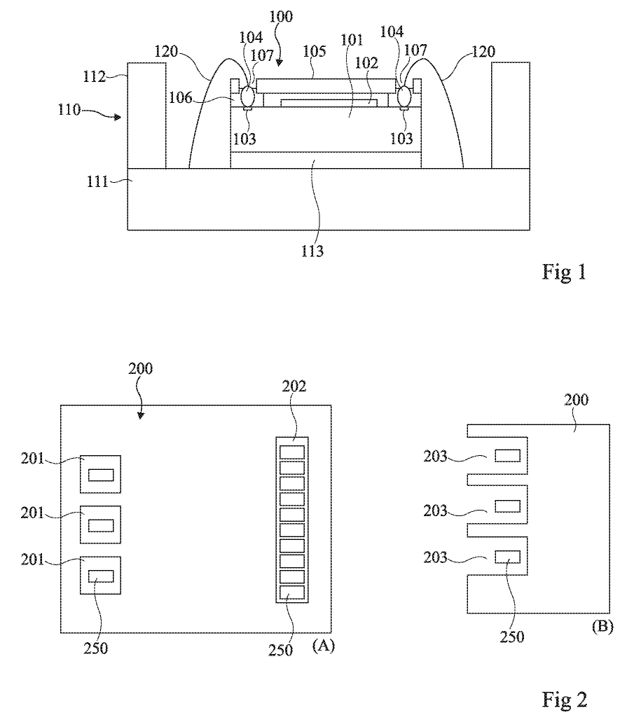

FIG. 1 is a cross-section view of an embodiment of an electronic integrated circuit (IC) chip 100 arranged in a package 110.

Electronic chip 100 is formed from a substrate 101, for example a silicon substrate. On a surface of substrate 101, at least one optical component 102 is formed. This optical component is, for example, an integrated circuit component configured to capture an image, such as an image sensor comprising an array of optical components. According to an embodiment, this optical component is an array of photodetection pixels. Each photodetection pixel comprises, for example, a microlens.

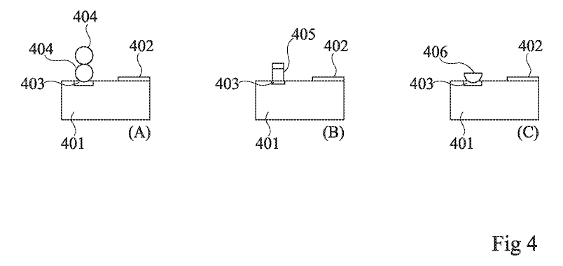

Electronic chip 100 further comprises at least one, generally a plurality of, connection pads 103 enabling to connect it to other electronic devices such as package 110. According to an embodiment, the connection pad(s) 103 are arranged at the periphery of optical component 102. Each connection pad 103 is topped by an electrical connection structure 104. According to an example, this electrical connection structure is a solder ball. Other types of electrical connection structures are described in relation with FIG. 4.

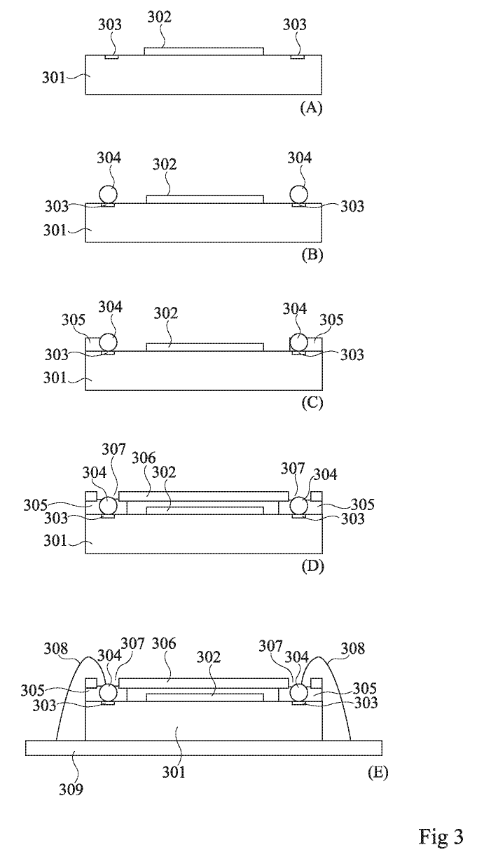

Electronic chip 100 further comprises a protective window 105 arranged above optical component 102. According to an example, window 105 is a plate made of an optically- transparent material, such as glass. According to another example, window 105 may be treated to implement one or more optical filters. An advantage of the use of such a protective window 105 is that it enables to protect optical component 102 from dust and debris that may arise during the method of manufacturing chip 100. Indeed, this window 105 may be installed as soon as component 102 has been manufactured. A method of manufacturing the chip and especially of installing window 105 is described in relation with FIG. 3.

According to an embodiment, window 105 is secured to substrate 101 via an adhesive layer 106. According to an embodiment, adhesive layer 106 is arranged solely at the periphery of optical component 102, surrounding but not covering the at least one optical component 102, and at the area of the connection pads 103 where it laterally encases the electrical connection structure 104. However, the thickness of adhesive layer 105 is smaller than the height of the electrical connection structure 104, so as to leave the top of the electrical connection structure accessible. According to an example, adhesive 106 is an electrically-insulating adhesive. According to an example, adhesive 106 need not be transparent as it does not cover any optical surface of the substrate 101, and in particular does not cover any part of the optical component 102.

According to an embodiment, protective window 105 comprises one or more openings 107 aligned with the locations of the pads 103 and configured to leave the electrical connection structure 104 accessible. Examples of openings 107 are described in detail in relation with FIG. 2.

According to an embodiment, protective window 105 has a width which is, at most, equal to the width of the substrate 101 of chip 100. According to an example, the protective window may have a width smaller than the width of substrate 101. This is an advantage of this embodiment.

Package 110 is a simplified package only comprising a substrate 111 and side walls 112. According to an example, substrate 111 is a laminated substrate. According to an example, side walls 112 are made of resin. Substrate 111 comprises, on its upper surface, one or more connection pads (not specifically illustrated).

Chip 100 is mounted in package 110 by being secured to the upper surface of substrate 111 via, for example, an adhesive layer 113.

According to an embodiment, chip 100 is further electrically coupled to package 110. More particularly, the connection pads 103 of chip 100 are electrically coupled to connection pads of the package at the upper surface of the substrate 111 via the electrical connection structure 104 and a connection wire 120. According to an embodiment, connection wire 120 is a solder wire, for example installed by a wire bonding method. According to an embodiment, a first end of the wire 120 is coupled, for example soldered, to the electrical connection structure 104 through the opening(s) 107 of protective window 105, and a second end of wire 120 is coupled, for example soldered, to a connection pad of the substrate 111 of package 110.

FIG. 2 comprises two views (A) and (B), each illustrating, partially or totally, examples of a protective window 200 of the type of the protective window 105 described in relation with FIG. 1.

According to an embodiment, the openings 201, 202 are openings of generally rectangular shape, but may have a general shape of the same type as the general shape in top view of a connection pad and its electrical connection structure 250 (symbolized by black blocks in FIG. 2), such as for example a generally circular, oval, or polygonal shape.

In view (A) of FIG. 2, window 200 comprises two types of openings 201 and 202 enabling to make the connection pads and their electrical connection structure 250 (corresponding to structure 104) accessible.

According to a first example, each opening 201 is intended to only make a single connection pad and its electrical connection structure 250 accessible. According to a second example, each opening 202 is intended to make a plurality of connection pads and their electrical connection structures 250 accessible.

In view (B) of FIG. 2, only part of window 200 is shown, and this comprises a type of opening 203. Opening 203 is an opening that has a side opening at the edge of protective window 200. Indeed, opening 203 is not entirely surrounded by walls formed by window 200.

According to a first example, each opening 203 is intended to make a single connection pad and its electrical connection structure 250 accessible. According to a second example, each opening 203 may be intended to make a plurality of connection pads and their electrical connection structures 250 accessible.

FIG. 3 comprises five views illustrating successive steps in an implementation mode of a method of manufacturing a chip of the type 100 described in relation with FIG. 1, and part of its installation in a package of the type of the package 110 described in relation with FIG. 1. More particularly, FIG. 3 shows in detail the installation of a protective window for a chip of the type of chip 100.

At the step of view (A) of FIG. 3, a substrate 301 comprising one or more optical components 302 formed on one of these surfaces, then referred to as the upper surface, is provided. Substrate 301 further comprises one or more connection pads 303 formed on this same upper surface. According to a preferred example, connection pads 303 are formed at the periphery of optical component(s) 302. The step of view (A) may comprise the methods of manufacturing the component(s) 302 and the connection pad(s) 303.

At the step of view (B) of FIG. 3, an electrical connection structure 304 is formed on each connection pad 303. Examples of the electrical connection structure are described in relation with FIG. 4.

At the step of view (C) of FIG. 3, an adhesive layer 305 intended to bond a protective window is deposited on a portion of the upper surface of substrate 301. More particularly, this adhesive layer 305 is arranged solely to surround the periphery of the optical component(s) 302 at the location of the pads 303 and laterally encasing the electrical connection structure 304. According to an example, the thickness of adhesive layer 305 is smaller than the height of the electrical connection structure 304 so that a top surface of the structure 304 is exposed.

At the step of view (D) of FIG. 3, a protective window 306 of the type of the protective window 105 described in relation with FIG. 1 is deposited on the structure obtained at the step of view (C). More particularly, protective window 306 comprises openings 307 of the type of the openings 107 described in relation with FIG. 1, and these openings are arranged so as to make the electrical connection structure 304 accessible.

Window 306 is bonded to this structure due to adhesive layer 305, and is, for example, pressed onto adhesive layer 305. Adhesive layer 305 may have overflowed at openings 307, which may be due to the pressing or simply to the weight of window 306. According to an embodiment, the thickness of adhesive layer 305 at openings 307 does not exceed 70% of the thickness of window 306. Further, according to an embodiment, the thickness of adhesive layer 305 at openings 307 does not exceed the height of the electrical connection structure 304.

At the end of the step of view (D), the installation of window 306 is complete, and if no other component is to be formed on the chip thus obtained, then the chip manufacturing process is complete.

At the step of view (E) of FIG. 3, the chip obtained at the end of the step of view (D) is installed in a package, of which only the substrate 309 is shown. According to an example, the chip is bonded to substrate 309, for example by using a bonding method.

Further, in the step of view (E), the electrical connection structures 304 are coupled to the connection pads of the package via connection wires. According to an example, a wire bonding method is implemented.

FIG. 4 comprises three views (A), (B), and (C) illustrating cross-section views of different types of electrical connection structures of the type of the electrical connection structure 104 described in relation with FIG. 1.

Each view (A), (B), and (C) shows a portion of a substrate 401 comprising on its upper surface an optical component 402 and a connection pad 403, for example metallic, for example made of copper.

In the view (A) of FIG. 4, the electrical connection structure is formed by a ball 404 of electrically-conductive material, such as a solder ball, or a stack of a plurality of balls 404. As a variant, ball(s) 404 are metal balls soldered to connection pad 403. Ball(s) 404 are, for example, connection elements of the type commonly referred to as "stud bump" or "stud ball". Such an element corresponds, for example, to the end of a metal wire, for example made of copper or of gold, formed by means of equipment of wire bonding type. The end of the metal wire is, for example, melted to form a ball, the ball being soldered to the connection pad 403, the wire then being broken away to leave the ball in place. Such balls can be stacked by repeating the operation.

In the view (B) of FIG. 4, the electrical connection structure is formed by a conductive pillar 405. According to an example, conductive pillar 405 may be formed by one or more layers of electrically-conductive materials. Conductive pillar 405 is, for example, a copper pillar.

In the view (C) of FIG. 4, the electrical connection structure is formed by a ball 406 of electrically-conductive material, such as a solder ball, a portion of which has been flattened, for example an upper portion.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An integrated circuit chip, comprising:
a substrate;
an optical component on a first surface of said substrate;
at least one electrical connection pad on said first surface of said substrate;
an electrical connection structure on the at least one electrical connection pad; and
a protective window arranged over said optical component and secured to said first surface of said substrate via an adhesive layer;
wherein the adhesive layer extends solely to surround at a periphery of said optical component, without covering any of the optical component, at a location of the at least one electrical connection pad and to laterally encase the electrical connection structure; and
wherein said protective window comprises at least one opening aligned with and configured to make said electrical connection structure accessible.

2. The integrated circuit chip according to claim 1, wherein said adhesive layer has a thickness smaller than a height of said electrical connection structure.

3. The integrated circuit chip according to claim 1, wherein said electrical connection structure comprises either a solder ball or a conductive pillar.

4. The integrated circuit chip according to claim 1, wherein an upper surface of said adhesive layer does not exceed more than 70% of a thickness of said protective window.

5. The integrated circuit chip according to claim 1, wherein an adhesive material of said adhesive layer is electrically-insulating.

6. The integrated circuit chip according to claim 1, wherein said at least one opening has a generally rectangular shape with a side opening at an edge of the protective window.

7. The integrated circuit chip according to claim 1, wherein said at least one opening is configured to make two or more electrical connection structures topping corresponding connection pads accessible.

8. The integrated circuit chip according to claim 1, wherein said protective window is one of an untreated glass window or a glass window comprising one or more optical filters.

9. The integrated circuit chip according to claim 1, wherein said optical component is an optical sensor.

10. An electronic device, comprising: the integrated circuit chip according to claim 1 and a package including a substrate to which the integrated circuit chip is mounted.

11. The device according to claim 10, further comprising a wire bonding wire the electrically couples said electrical connection structure to a connection terminal of substrate.

12. A method of manufacturing, comprising the following steps:
providing an integrated circuit chip including an optical component arranged on a first surface of a chip substrate and at least one electrical connection pad arranged on said first surface of said chip substrate;
mounting electrical connection structure on the at least one electrical connection pad;
depositing an adhesive layer that extends solely to surround at a periphery of said optical component, without covering any of the optical component, at a location of the at least one electrical connection pad and to laterally encase the electrical connection structure;
arranging a protective window over said at least one component, wherein said protective window comprises at least one opening aligned with and configured to make said electrical connection structure accessible; and
bonding the protective window to the integrated circuit chip via said adhesive layer.

13. The method according to claim 12, further comprising forming the at least one opening in the protective window by implementing a reactive ion etching operation or a laser etching operation.

14. The method according to claim 12, wherein said electrical connection structure comprises either a solder ball or a conductive pillar.

15. The method according to claim 12, wherein an adhesive material of said adhesive layer is electrically-insulating.

16. The method according to claim 12, wherein said at least one opening has a generally rectangular shape with a side opening at an edge of the protective window.

17. The method according to claim 12, wherein said at least one opening is configured to make two or more electrical connection structures topping corresponding connection pads accessible.

18. The method according to claim 12, wherein said protective window is one of an untreated glass window or a glass window comprising one or more optical filters.

19. The method according to claim 1, wherein said optical component is an optical sensor.
